(19) United States
(12) Patent Application Publication
(10) Pub. No.: US 2013/0146984 A1
(43) Pub. Date: Jun. 13, 2013

(54) SEMICONDUCTOR DEVICE AND METHOD OF MANUFACTURING THE SAME

(71) Applicant: Jung Ryul AHN, Namyangju-si (KR)

(72) Inventor: Jung Ryul AHN, Namyangju-si (KR)

(73) Assignee: SK HYNIX INC., Icheon-si (KR)

(21) Appl. No.: 13/601,437

(22) Filed: Aug. 31, 2012

(30) Foreign Application Priority Data
Dec. 13, 2011 (KR) 10-2011-0133704

(51) Int. Cl. H01L 21/762; H01L 29/78

(52) U.S. Cl. 257/368; 438/435; 257/E29.255; 257/E21.546

(57) ABSTRACT

A semiconductor device includes isolation layers formed at isolation regions of a semiconductor substrate, silicon patterns formed over the semiconductor substrate between the isolation layers, insulating layers formed between the silicon patterns and the semiconductor substrate, and junctions formed in the semiconductor substrate between the silicon patterns, wherein each of the silicon patterns has a sloped top surface.

### CROSS-REFERENCE TO RELATED APPLICATION

The present application claims priority to Korean patent application number 10-2011-0133704 filed on Dec. 13, 2011, in the Korean Intellectual Property Office, the entire disclosure of which is incorporated by reference herein.

### BACKGROUND

1. Field of Invention

Embodiments of the present invention relate generally to a semiconductor device and a method of manufacturing the same and, more particularly, to a semiconductor device including a silicon layer and a method of manufacturing the same.

2. Related Art

With continued miniaturization of a semiconductor device, pattern width and spacing between adjacent patterns decrease. The pattern width and the spacing between patterns are determined according to a resolution of exposure equipment.

For these reasons, a decrease in the pattern width and the spacing between patterns may have limitations due to a resolution limit of exposure equipment.

### BRIEF SUMMARY

According to an embodiment of the present invention, fine patterns may be formed even with an exposure equipment having relatively low resolution.

A semiconductor device according to an embodiment of the present invention includes isolation layers formed at isolation regions of a semiconductor substrate, silicon patterns formed over the semiconductor substrate between the isolation layers, insulating layers formed between the silicon patterns and the semiconductor substrate, and junctions formed in the semiconductor substrate between the silicon patterns, wherein both top corners of each of the silicon patterns are asymmetrical relative to each other.

A method of manufacturing a semiconductor device according to an embodiment of the present invention includes forming first isolation layers in a semiconductor substrate, wherein the first isolation layers have top portions extending higher than the semiconductor substrate, forming an insulating layer over a surface of the semiconductor substrate, forming silicon films along both sidewalls of each of the top portions of the first isolation layers, etching the insulating layer between the silicon films and the semiconductor substrate, forming second isolation layers in etched portions of the semiconductor substrate and between the silicon films, forming a dielectric layer and a conductive layer over an entire structure including the second isolation layers, and forming control gates and floating gates by etching the conductive layer, the dielectric layer and the silicon films.

### BRIEF DESCRIPTION OF THE DRAWINGS

FIGS. 1A and 1B are views of a semiconductor device according to an embodiment of the present invention;

FIGS. 2A to 2H are cross-sectional views illustrating a method of manufacturing a semiconductor device according to an embodiment of the present invention; and

FIGS. 3A to 3H are cross-sectional views illustrating a method of manufacturing a semiconductor device according to an embodiment of the present invention.

### DESCRIPTION OF EMBODIMENTS

Hereinafter, various embodiments of the present disclosure will be described in detail with reference to the accompanying drawings. The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

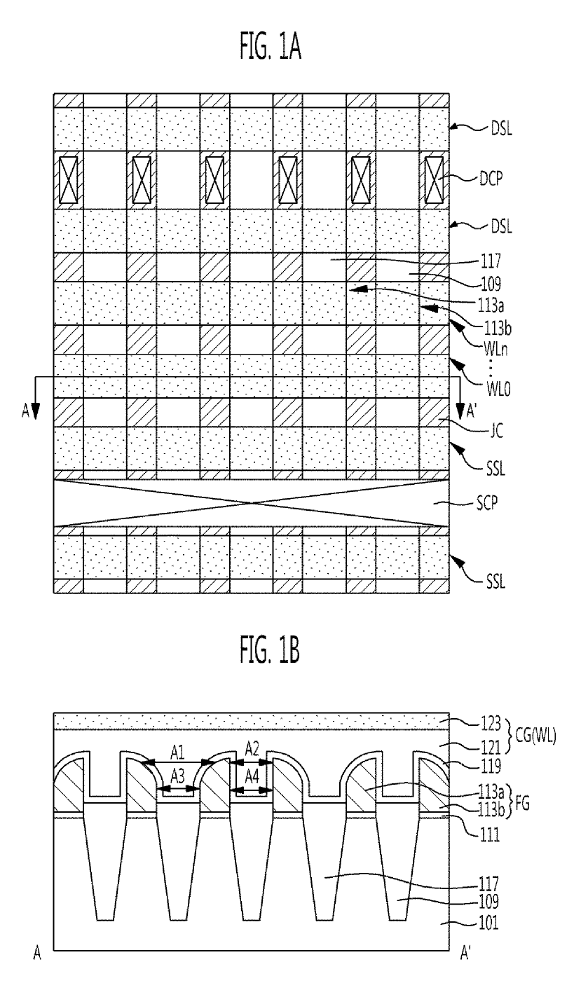

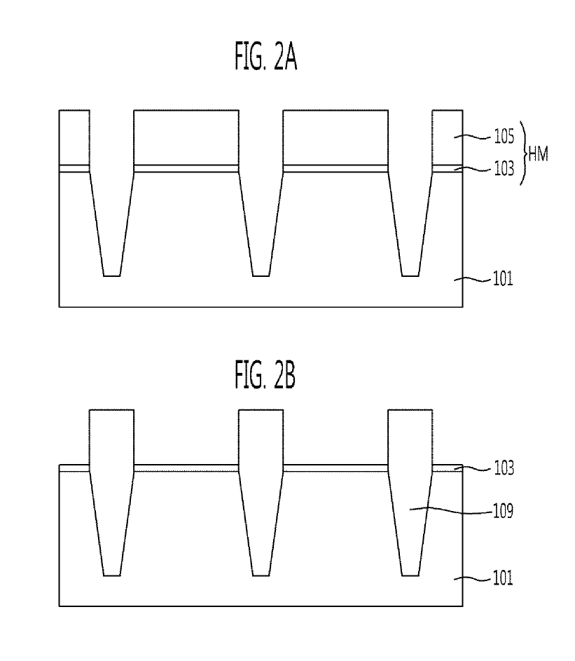

FIGS. 1A and 1B are views of a semiconductor device according to an embodiment of the present invention.

Referring to FIGS. 1A and 1B, a semiconductor substrate 101 of a semiconductor device (e.g., a nonvolatile memory device such as NAND flash memory device) may be divided into a cell region and a peripheral circuit region. Isolation layers (e.g., 109 and 117) may be formed at isolation regions of the cell region. For example, the isolation layers may have linear shapes arranged side by side, e.g., the isolation layers may be parallel to each other. Regions of the semiconductor substrate 101 between the isolation layers (e.g., 109 and 117) are defined as active regions. Lower portions of the isolation layers (e.g., 109 and 117) may be formed in trenches formed in the semiconductor substrate 101, and upper portions thereof may be formed over the semiconductor substrate 101. It should be readily understood that the meaning of “on” and “over” in the present disclosure should be interpreted in the broadest manner such that “on” not only mean “directly on” something but also include the meaning of “on” something with an intermediate feature or a layer therebetween and that “over” not only means the meaning of “over” something may also include the meaning it is “over” something with no intermediate feature or layer therebetween (i.e., directly on something). Word lines WL0 to WLn and select lines (e.g., DSL and SSL) may be formed in a direction crossing the isolation layers (e.g., 109 and 117). The word lines WL0 to WLn may correspond to control gates CG of memory cells. The word lines WL0 to WLn and the select lines DSL and SSL each may comprise a polysilicon layer 121 and a silicide layer 123 that are stacked. Junctions JC may be formed in the semiconductor substrate 101 between each adjacent word lines WL0 to WLn and between a select line (e.g., DSL or SSL) and an adjacent word line WL0 or WLn so that the junctions JC are used as sources or drains.

Drain contact plugs DCP may be formed in the junctions JC between drain select lines DSL. A source contact plug SCP may be formed between source select lines SSL and be in the form of a line that is coupled to the junctions JC.

Insulating layers 111 and silicon films 113a and 113b may be stacked between the lines (e.g., WL0 to WLn, DSL and SSL) and the active regions of the semiconductor substrate 101. Here, the insulating layers 111 may be used as tunnel insulating layers. Each of the insulating layers 111 may comprise one or more of an oxide layer and a nitride layer. For example, the insulating layers 111 may be formed by sequentially stacking an oxide layer, a nitride layer and an oxide layer. In particular, the insulating layer 111 may comprise an oxide layer that includes conductive dots of at least one of Ru, Si, Ti and Pt. When the insulating layer 111 comprises an oxide layer, a nitride layer and an oxide layer that are stacked, the nitride layer may be thin so that electrons pass through it without being trapped inside.

The silicon films 113a and 113b that are used as floating gates FG may contain carbon impurities and be formed of amorphous silicon. N type impurities or P type impurities may be implanted into the silicon film 113a or 113b by using an ion implantation process. Each of the silicon films 113a and 113b may have a sloped top surface. For example, an upper part of the silicon film 113a or 113b may be narrower in width than a lower part thereof. A slope of one sidewall may be smaller that of the other sidewall. In addition, one pair of silicon films 113a and 113b may have symmetrical shapes.

According to the structures of the silicon layers 113a and 113b, among first to third silicon patterns that are arranged in a direction crossing the first isolation layers 109, a top space A1 between the first and second silicon patterns (e.g., 113a and 113b) may be larger than a top space A2 between the second and third silicon patterns (e.g., 113b and 113a).

In addition, among the first to third silicon patterns that are arranged in a direction crossing the first isolation layers 109, the top space A1 between the first and second silicon patterns (e.g., 113a and 113b) may be larger than a bottom space A3 therebetween, and the top space A2 between the silicon patterns (e.g., 113a and 113b) may be substantially the same as a bottom space A4 therebetween.

Dielectric layers 119 may be formed between the control gates CG and the floating gates FG. The dielectric layers 119 each may comprise one or more of an oxide layer and a nitride layer. For example, the dielectric layers 119 may be formed by sequentially stacking an oxide layer, a nitride layer and an oxide layer. An oxide layer or a nitride layer may be further formed over or under the stack. A high dielectric insulating layer with a high dielectric constant may replace the oxide layer or the nitride layer of the dielectric layer 119.

A method of manufacturing the semiconductor device having the above-described structure will be described below.

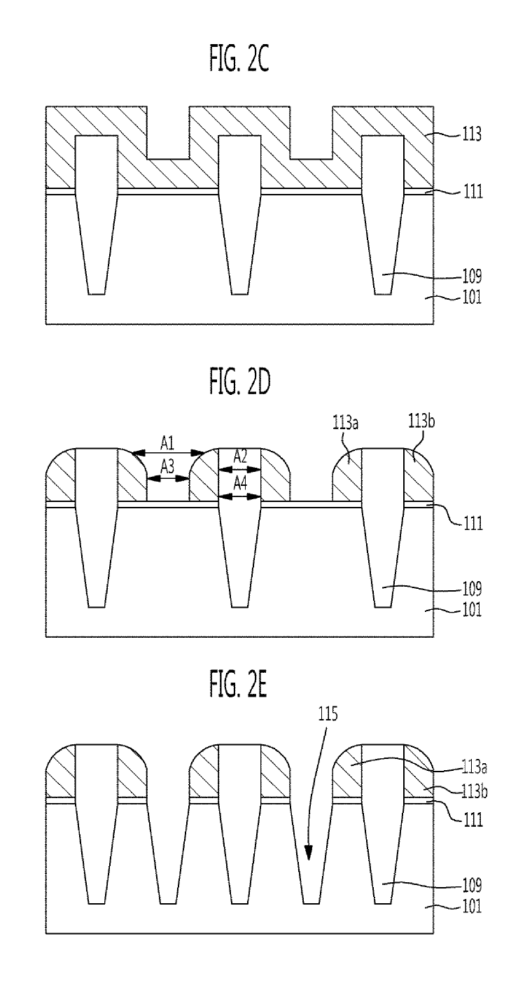

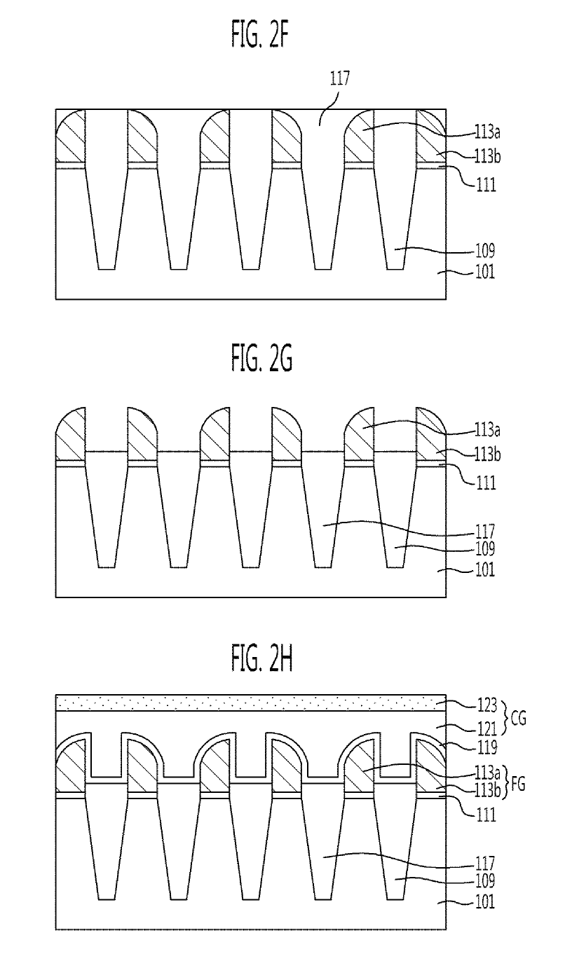

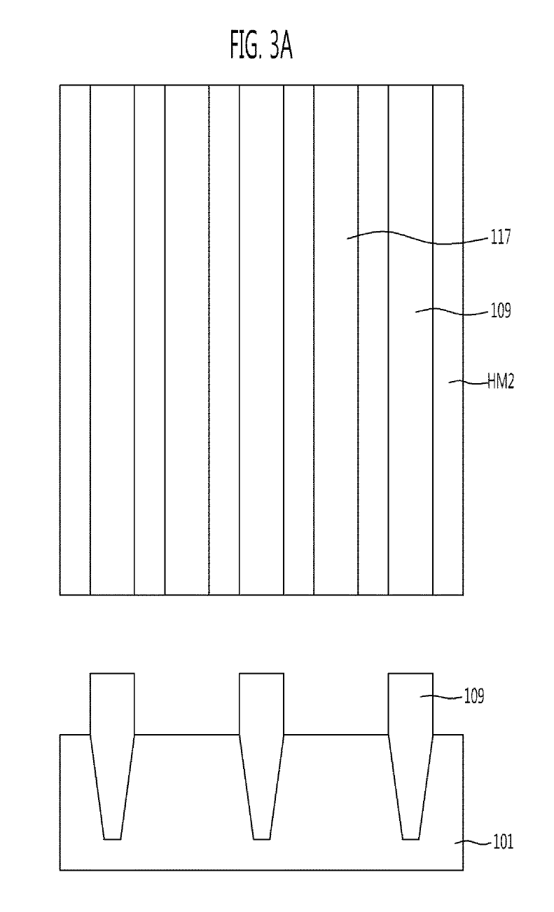

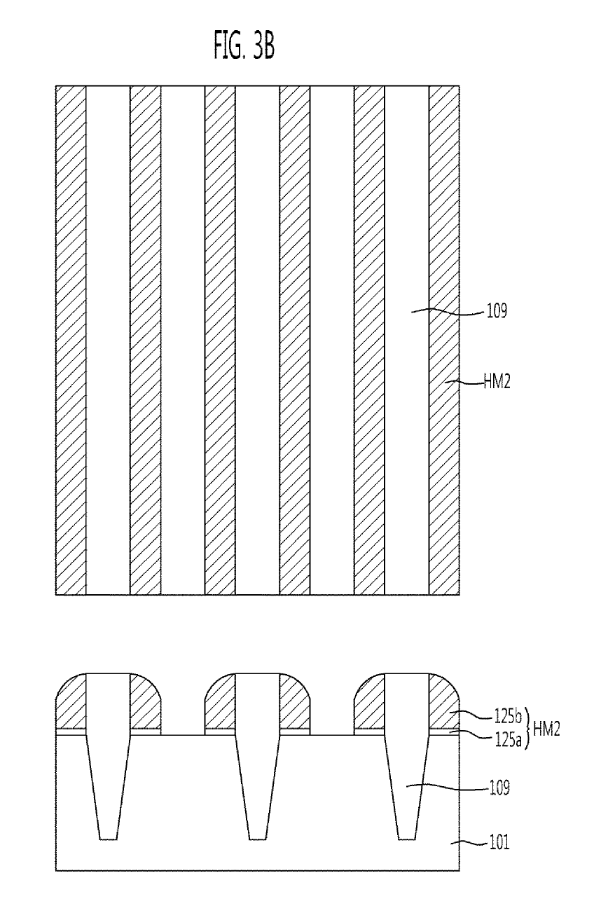

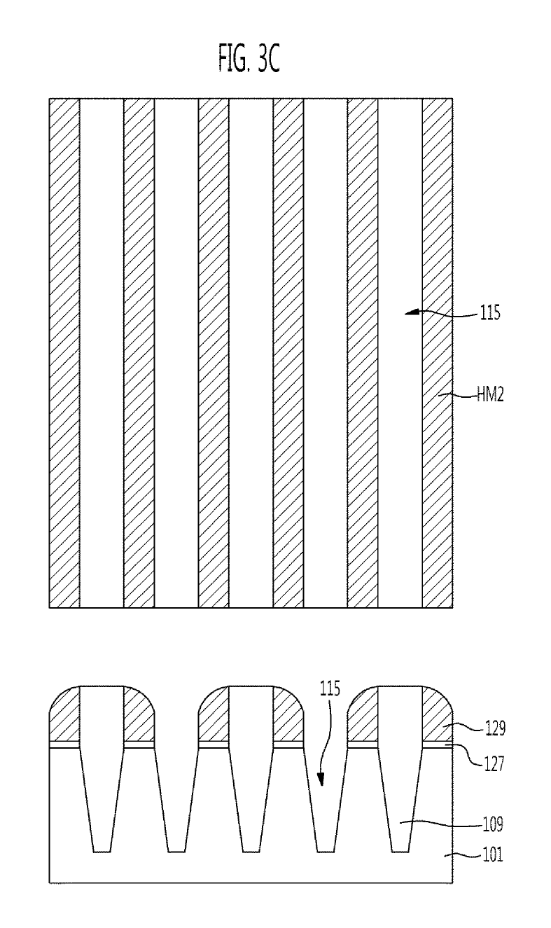

FIGS. 2A to 2H are cross-sectional views illustrating a method of manufacturing a semiconductor device according to an embodiment of the present invention.

Referring to FIG. 2A, a hard mask pattern HM is formed on the semiconductor substrate 101 to expose some portions of the semiconductor substrate 101 that isolation regions are to be formed. The hard mask pattern HM may comprise one or more of an oxide layer and a nitride layer. For example, the mask pattern HM may be formed by stacking the oxide layer and the nitride layer. The hard mask pattern HM in the cell region may expose some portions of the semiconductor substrate 101 that the isolation regions are to be formed. The exposed portions may have linear shapes arranged side by side, e.g., the exposed portions may be parallel to each other.

An oxide layer 103 and a nitride layer 105 may be sequentially formed over the semiconductor substrate 101. The nitride layer 105 may be coated with a photoresist, and exposure and development processes may be performed to form a photoresist pattern (not shown) that exposes some portions of the semiconductor substrate 101 that odd-numbered or even-numbered isolation regions are to be formed. The exposed portions may have linear shapes arranged side by side, e.g., the exposed portions may be parallel to each other. The photoresist pattern may expose some portions of the semiconductor substrate 101 such that even-numbered or odd-numbered isolation regions are spaced apart by the minimum space that may be defined by a resolution of exposure equipment. The nitride layer 105 and the oxide layer 103 may be etched by an etch process using the photoresist pattern as an etch mask to thus form the hard mask pattern HM. After the photoresist pattern is removed, the semiconductor substrate 101 may be etched by an etch process using the hard mask pattern HM as an etch mask to thus form trenches 107.

The thickness of the hard mask pattern HM may determine the height of a floating gate silicon layer and a coupling ratio between a floating gate and a control gate in subsequent processes. Thus, the thickness of the hard mask pattern HM may be controlled by taking all these considerations into account.

Referring to FIG. 2B, an insulating layer may be formed to fill the trenches 107, and the insulating layer over the hard mask pattern HM may be removed to form first isolation layers 109 in regions in which the trenches 107 are formed. Before the insulating layer is formed, an oxide layer (not shown) may be formed along an inner wall of each of the trenches 107 by performing an oxidation process. The hard mask pattern HM may be removed. As a result, top portions of the first isolation layers 109 may be formed at higher positions than the semiconductor substrate 101 by the thickness of the hard mask pattern HM.

Referring to FIG. 2C, the insulating layers 111 may be formed over the semiconductor substrate 101 between the first isolation layers 109. As for a flash memory device, the insulating layers 111 may be used as tunnel insulating layers. The insulating layers 111 may be formed by performing an oxidation process.

In addition, the insulating layer 111 may comprise one or more of an oxide layer and a nitride layer. For example, the insulating layers 111 may be formed by sequentially stacking an oxide layer, a nitride layer and an oxide layer. Here, the nitride layer may be thin so that electrons pass through it without being trapped. The insulating layer 111 may be formed by forming an oxide layer, nitriding the oxide layer to form a nitride layer and forming another oxide layer. In another example, at least one of materials consisting of Ru, Si, Ti and Pt may be supplied to implant conductive dots into the insulating layer 111 when the insulating layer 111 is formed.

A silicon layer 113 may be formed over protrusions of the first isolation layers 109 and the insulating layer 111. The silicon layer 113 may have a thickness that maintains stepped portions formed by the protrusions of the first isolation layers 109. In particular, the width of each floating gate and widths of isolation layers to be additionally formed between the first isolation layers 109 may be determined by the thickness of the silicon layer 113 (e.g., the thickness of the silicon layer formed along sidewalls of the protrusions of the first isolation layers). Thus, the thickness of the silicon layer 113 may be controlled by taking all these considerations into account.

While the silicon layer 113 is formed, carbon impurities may be implanted in the silicon layer 113 in order to prevent the silicon layer 113 from being etched when the semiconductor substrate 101 is etched in subsequent processes.

Referring to FIG. 2D, the silicon layer 113 may be etched so that the silicon layer 113 remains, for example, only at both sidewalls of each of the protrusions of the first isolation layers 109. Here, the silicon layer 113 may be etched by a blanket etch-back process and remain as spacers at both sidewalls of each of the protrusions of the first isolation layers 109. As a result, the silicon films 113a and 113b may be formed at both sidewalls of each of the protrusions of the first isolation layers 109. The silicon films 113a and 113b may be additionally etched to form silicon patterns in subsequent processes. The silicon films 113a and 113b may be formed of amorphous silicon, and N type impurities or P type impurities may be implanted into the silicon films 113a and 113b by using an ion implantation process after the silicon films 113a and 113b are formed.

As the silicon films 113a and 113b are formed as described above, each of the silicon films 113a and 113b may have a sloped top surface. For example, the silicon layer 113a may have an upper part that is narrower in width than a lower part. A slope of one sidewall may be smaller that of the other sidewall. In addition, one pair of silicon films 113a and 113b may have symmetrical shapes.

In addition, as described above referring to FIG. 1B, among first to third silicon films that are arranged in a direction crossing the first isolation layers 109, the top space A1 between the first and second silicon films (e.g., 113a and 113b) may be greater than the top space A2 between the second and third silicon films (e.g., 113b and 113a). Here, the top space A2 between the second and third silicon films (e.g., 113b and 113a) may correspond to the width of the first isolation layer 109. In addition, among the first to third silicon films that are arranged in a direction crossing the first isolation layer 109, the top space A1 between the first and second silicon films (e.g., 113a and 113b) may be greater than the bottom space A3 therebetween, and the top space A2 between the second and third silicon films (e.g., 113b and 113a) may be substantially the same as the bottom space A4 therebetween. The top space A2 and the bottom space A4 between the second and third silicon films (e.g., 113b and 113a) may correspond to the width of the first isolation layer 109.

Referring to FIG. 2E, the insulating layer 111 and the semiconductor substrate 101 between the silicon films 113a and 113b may be etched by performing an etch process using the silicon films 113a and 113b as an etch mask, thus forming trenches 115. Since the silicon films 113a and 113b contain carbon impurities, unnecessary etching of the silicon films 113a and 113b may be minimized when the semiconductor substrate 101 is etched. In order to further minimize unnecessary etching of the silicon layers 113a and 113b, an annealing process may be performed such that the silicon films 113a and 113b have an amorphous silicon state, and the semiconductor substrate 101 may be etched.

Referring to FIG. 2F, after an insulating layer is formed over an entire structure to fill the trenches 115, a planarization process such as chemical mechanical polishing may be performed until the silicon films 113a and 113b are exposed to thus form second isolation layers 117 in regions in which the trenches 115 are formed. Before the insulating layer is formed, an oxidation process may be performed to thus form an oxide layer (not shown) in an inner wall of each trench. Top portions of the second isolation layers 117 may be formed at higher positions than the semiconductor substrate 101 by the height of each of the silicon layers 113a and 113b. As a result, the second isolation layers 117 may be automatically aligned between the first isolation layers 109.

In addition, the spacing between the isolation layers (e.g., 109 and 117) may be controlled to be smaller than the minimum space that may be defined by the resolution of the exposure equipment by performing exposure and development processes once. In addition, since the widths of the silicon films 113a and 113b may be controlled by deposition thickness of the silicon layer 113 formed as described above referring to FIG. 2C, the widths of the silicon films 113a and 113b may be controlled regardless of resolution capabilities of the exposure equipment. In particular, since the widths of the active regions defined between the isolation layers (e.g., 109 and 117) may be determined by the widths of the silicon layers 113a and 113b, the widths of the active regions may be controlled regardless of the resolution capabilities of the exposure equipment. Therefore, the isolation layers (e.g., 109 and 117) and the silicon films 113a and 113b may be formed to have widths and spaces smaller than the resolution capabilities of the exposure equipment.

Referring to FIG. 2G, the top portions of the isolation layers (e.g., 109 and 117) may be etched to expose the upper sidewalls of the silicon layers 113a and 113b. Here, the top portions of the isolation layers (e.g., 109 and 117) may be etched without exposing edges of the insulating layer 111.

Referring to FIG. 2H, the control gates CG may be formed in a direction crossing the isolation layers (e.g., 109 and 117). After the dielectric layer 119, a polysilicon layer 121 and a conductive layer 123 are formed over the entire structure, the conductive layer 123, the polysilicon layer 121 and the dielectric layer 119 may be etched such that the polysilicon layer 121 and the conductive layer 123 may remain in linear shape along a direction crossing that isolation layers (e.g., 109 and 117). Here, the dielectric layer 119 may comprise one or more of an oxide layer and a nitride layer. For example, the dielectric layers 119 be formed by sequentially stacking an oxide layer, a nitride layer and an oxide layer, and an oxide layer or a nitride layer may be further formed over or under the stacked structure. A high dielectric insulating layer with a high dielectric constant may replace the oxide layer or the nitride layer of the dielectric layer 119. The conductive layer 123 may comprise a metal silicide layer.

Therefore, the control gates CG may include the polysilicon layer 121 and the conductive layer 123 that are stacked. As the silicon films 113a and 113b exposed between the control gates CG are removed, the silicon patterns (e.g., 113a and 113b) remain, for example, only under the control gates CG, and the silicon patterns (e.g., 113a and 113b) become the floating gates FG.

As the above-described processes are completed, the word lines WL0 to WLn, the drain select lines DSL and the source select lines SSL are formed.

The junctions JC may be formed in the semiconductor substrate 101 between the lines (e.g., DSL, SSL and WL0 to WLn). An interlayer insulating layer (not shown) may be formed, contact holes (not shown) may be formed in the interlayer insulating layer, and the drain contact plugs DCP and the source contact plug SCP may be formed in the contact holes. The drain contact plugs DCP may be formed in the junctions JC between the drain select lines DSL, and the source contact plug SCP, having a linear shape, may be formed between the source select lines SSL.

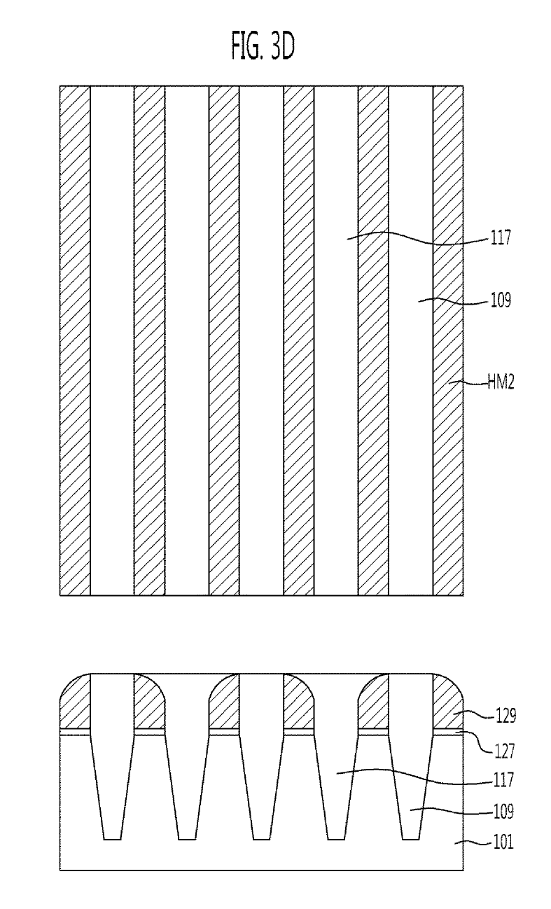

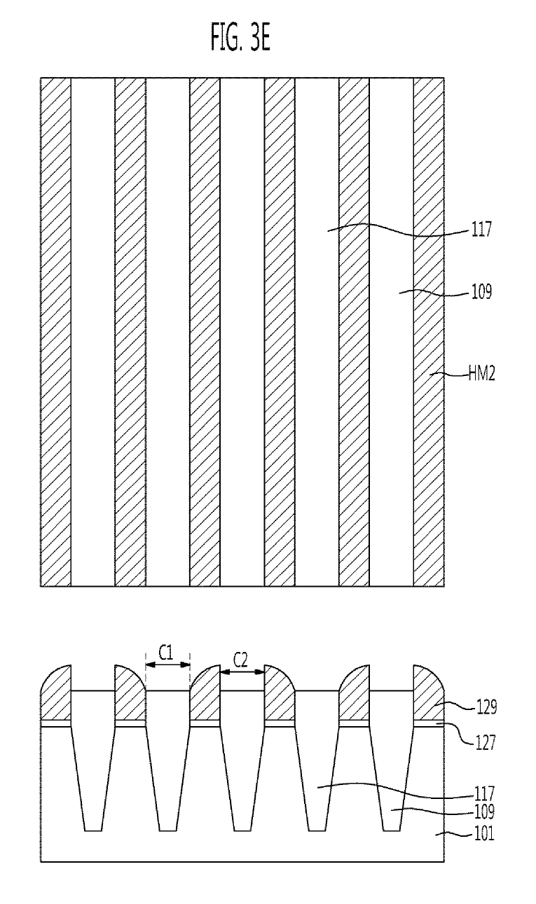

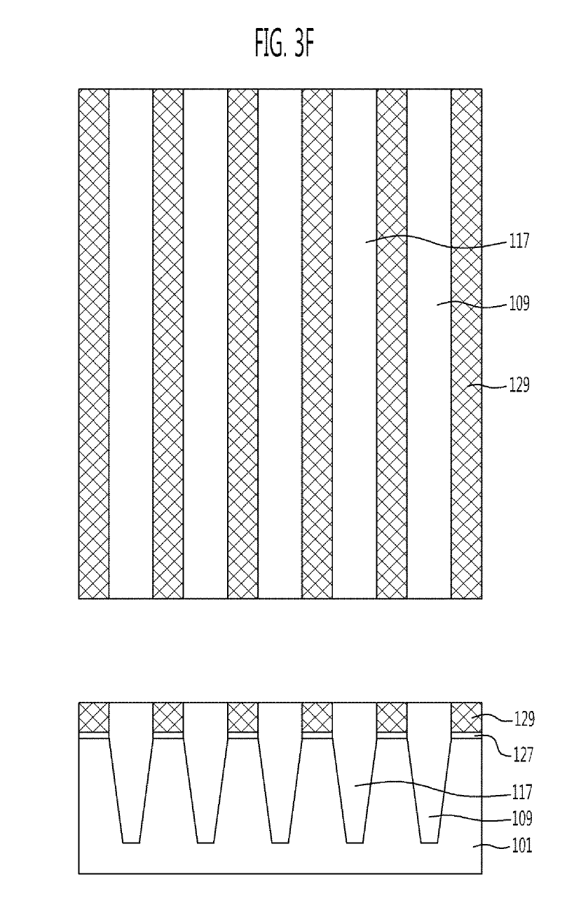

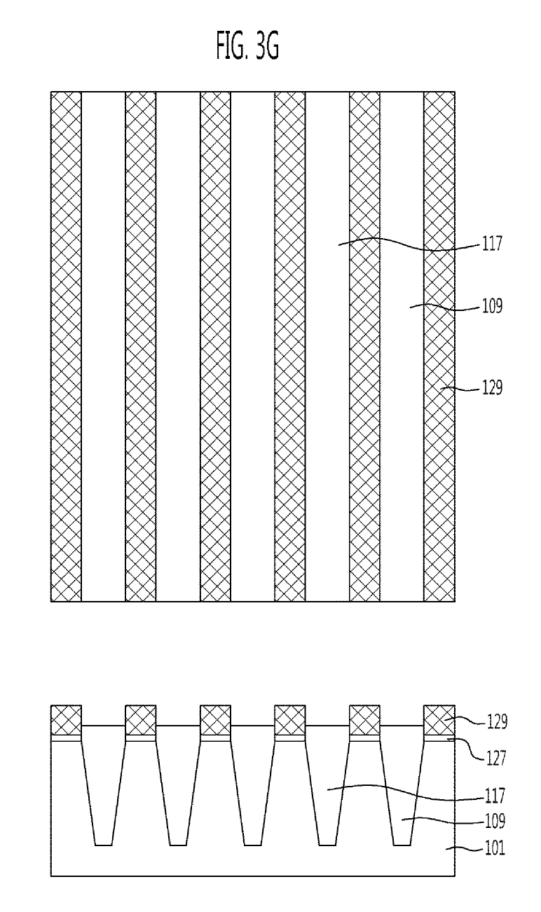

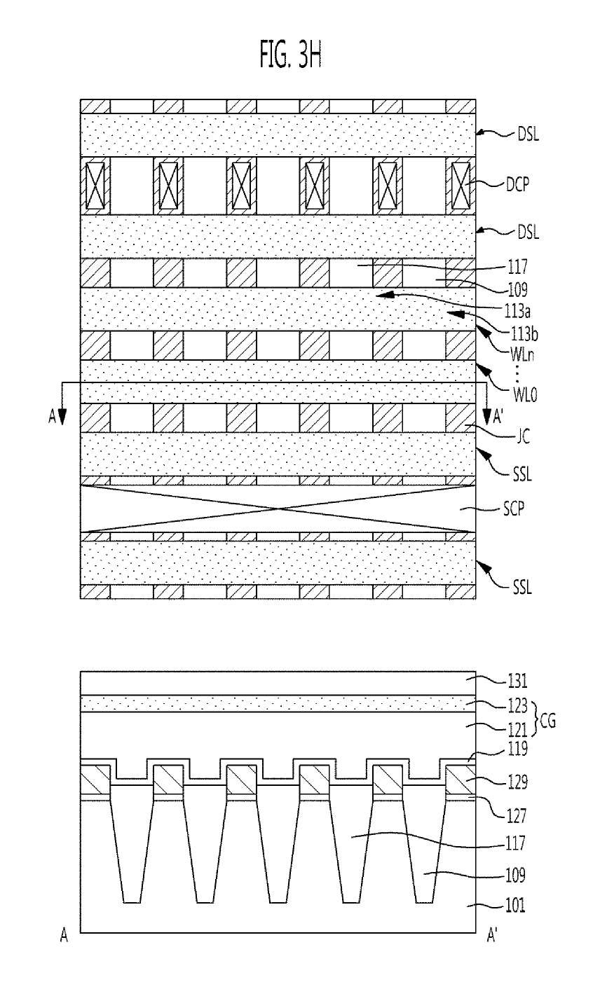

FIGS. 3A to 3H are cross-sectional views illustrating a method of manufacturing a semiconductor device according to an embodiment of the present invention.

Referring to FIG. 3A, the first isolation layers 109 may be formed at isolation regions of the semiconductor substrate 101, and top portions of the first isolation layers 109 may be formed at higher positions than the semiconductor substrate 101. Therefore, each first isolation layer 109 may be formed twice as far from an adjacent first isolation layer 109 as the target interval. In other words, either even or odd numbered isolation layers may be formed among the first isolation layers 109 to be formed. In addition, the first isolation layers 109 may have linear shapes arranged side by side, e.g., the isolation layers may be parallel to each other.

Referring to FIG. 3B, hard mask spacers HM2 may be formed along sidewalls of each protrusion of the first isolation layers 109. Regions of the semiconductor substrate 101 which are exposed between the hard mask spacers HM2 may be determined according to the thickness of each of the hard mask spacers HM2 formed along the sidewalls of the first isolation layers 109. The exposed regions of the semiconductor substrate 101 become another isolation regions. Therefore, the width of each another isolation regions may be determined according to the thickness of each of the hard mask spacers HM2 formed along the sidewalls of the first isolation layers 109.

In addition, since regions in which the hard mask spacers HM2 are formed are defined as active regions, the width of each active region may be determined by the thickness of the hard mask spacer HM2 in substantially the same manner as the width of the isolation region and the width of the active regions in which the trench 115 is formed may be determined according to the thickness of each of the silicon films 113a and 113b as described referring to FIG. 2D.

The hard mask spacers HM2 may have the oxide layer 125a and the nitride layer 125b that are stacked.

Referring to FIG. 3C, the semiconductor substrate 101 between the hard mask spacers HM2 may be etched by performing an etch process using the hard mask spacers HM2 as an etch mask to thus form the trenches 115.

Referring to FIG. 3D, an insulating layer may be formed over the entire structure to fill the trenches 115, and a planarization process such as chemical mechanical polishing may be performed until the hard mask spacers HM2 are exposed to thus form the second isolation layers 117 in regions in which the trenches 115 are formed. An oxidation process may be performed to form an oxide layer (not shown) along an inner wall of each of the trenches before the insulating layer is formed. Top portions of the second isolation layers 117 may be formed at higher positions than the semiconductor substrate 101 by the height of the hard mask spacer HM2. As a result, the second isolation layers 117 may be automatically aligned between the first isolation layers 109.

In addition, in substantially the same manner as described referring to FIG. 2F, the spacing between the isolation layers (e.g., 109 and 117) may be controlled be smaller than the minimum space that may be defined by the resolution of the exposure equipment by performing exposure and development processes once.

Referring to FIG. 3E, the top portions of the isolation layers (e.g., 109 and 117) may be etched to expose upper sidewalls of the hard mask spacers HM2. Here, the isolation layers (e.g., 109 and 117) may be etched without exposing edges of the insulating layer 111. An etch rate of the top portions of the isolation layers (e.g., 109 and 117) may be controlled so that remaining widths C1 and C2 of the isolation layers (e.g., 109 and 117) may be substantially the same as each other.

Referring to FIG. 3F, the hard mask spacers HM2 may be removed. Insulating layers 127 and silicon films 129 may be formed over the semiconductor substrate 101 between the isolation layers (e.g., 109 and 117). Here, the insulating layers 127 may be used as tunnel insulating layers, and the silicon films 129 may be used as floating gates.

The semiconductor substrate 101 between the isolation layers (e.g., 109 and 117) may be oxidized to form the insulating layers 127. The silicon films 129 may be formed over the entire structure to fill spaces between the protrusions of the isolation layers (e.g., 109 and 117), and a polishing process may be performed until top surfaces of the isolation layers (e.g., 109 and 117) are exposed. Therefore, the insulating layer 127 and the silicon films 129 may be stacked on the semiconductor substrate 101 between the isolation layers (e.g., 109 and 117). The silicon films 129 may have N-type impurities or P-type impurities and be formed in a single crystal state or a polycrystalline state.

As a result, the silicon films 129 may be automatically aligned on the semiconductor substrate 101 (e.g., active regions) between the isolation layers (e.g., 109 and 117). In addition, the spacing between the silicon films 129 may be controlled to be smaller than the minimum space that may be defined by the resolution of the exposure equipment.

Referring to FIG. 3G, the top portions of the isolation layers (e.g., 109 and 117) may be additionally etched to expose upper sidewalls of the silicon films 129. Here, the top portions of the isolation layers (e.g., 109 and 117) may be etched without exposing edges of the insulating layer 111.

Referring to FIG. 3H, the control gates CG may be formed in a direction crossing the isolation layers (e.g., 109 and 117). The dielectric layer 119, the polysilicon layer 121, the conductive layer 123 and a hard mask layer 131 may be formed over the entire structure. The hard mask layer 131, the conductive layer 123, the polysilicon layer 121 and the dielectric layer 119 may be etched so that the polysilicon layer 121 and the conductive layer 123 may have linear shapes arranged along a direction crossing the isolation layers (e.g., 109 and 117). As described above, the dielectric layer 119 may comprise one or more of an oxide layer and a nitride layer. For example, the dielectric layers 119 may be formed by sequentially stacking an oxide layer, a nitride layer and an oxide layer, and an oxide layer or a nitride layer may be further formed over or under the stacked structure. A high dielectric insulating layer with a high dielectric constant may replace the oxide layer or the nitride layer of the dielectric layer 119. The conductive layer 123 may comprise a metal silicide layer.

Therefore, the control gates CG each may include the polysilicon layer 121 and the conductive layer 123 that are stacked. As the silicon films 129 exposed between the control gates CG are removed, silicon patterns (e.g., 129) may remain under the control gates CG, and the silicon patterns (e.g., 129) may become the floating gates FG.

As the above-described processes are completed, the word lines WL0 to WLn, the drain select lines DSL and the source select lines SSL may be formed.

Then, the junctions JC may be formed in the semiconductor substrate 101 between the lines (e.g., DSL, SSL and WL0 to WLn). An interlayer insulating layer (not shown) may be formed, contact holes (not shown) may be formed in the interlayer insulating layer, and the drain contact plugs DCP and the source contact plug SCP may be formed in the contact holes. The drain contact plugs DCP may be formed in the junctions JC between the drain select lines DSL, and the source contact plug SCP, having a linear shape, may be formed between the source select lines SSL.

According to an embodiment of the present invention, patterns of smaller width and spacing than the resolution of exposure equipment may be formed to thus improve an integration degree of a device.

What is claimed is:

1. A semiconductor device, comprising:
isolation layers formed at isolation regions of a semiconductor substrate;
silicon patterns formed over the semiconductor substrate between the isolation layers;
insulating layers formed between the silicon patterns and the semiconductor substrate; and
junctions formed in the semiconductor substrate between the silicon patterns,
wherein each of the silicon patterns has a sloped top surface.

2. The semiconductor device of claim 1, wherein the isolation layers have linear shapes arranged side by side.

3. The semiconductor device of claim 2, further comprising:
dielectric layers formed over the silicon patterns; and
conductive layers formed over the dielectric layers,
wherein the conductive layers are arranged along a direction crossing the isolation layers, and the silicon patterns are arranged under the conductive layers.

4. The semiconductor device of claim 1, wherein the silicon patterns comprises first to third silicon patterns arranged in a direction crossing the isolation layers and a top space between the first and second silicon patterns is greater than a top space between the second and third silicon patterns.

5. The semiconductor device of claim 1, wherein the silicon patterns comprises first to third silicon patterns arranged in a direction crossing the isolation layers and a top space between the first and second patterns is substantially the same as a bottom space therebetween, and a top space between the second and third silicon patterns is greater than a bottom space therebetween.

6. The semiconductor device of claim 1, wherein the insulating layers comprise one or more of an oxide layer and a nitride layer.

7. The semiconductor device of claim 1, wherein the insulating layers comprise one or more of oxide layers and one or more of nitride layers that are formed by stacking the layers.

8. The semiconductor device of claim 1, wherein the insulating layers contain conductive dots.

9. The semiconductor device of claim 8, wherein the conductive dots include one or more of Ru, Si, Ti and Pt.

10. A method of manufacturing a semiconductor device, the method comprising:
forming first isolation layers in a semiconductor substrate, wherein the first isolation layers have top portions formed at higher positions than the semiconductor substrate;
forming an insulating layer over a surface of the semiconductor substrate;
forming silicon films along both sidewalls of each of the top portions of the first isolation layers;
etching the insulating layer between the silicon films and the semiconductor substrate;
forming second isolation layers in etched portions of the semiconductor substrate and between the silicon films;
forming a dielectric layer and a conductive layer over an entire structure including the second isolation layers; and
forming control gates and floating gates by etching the conductive layer, the dielectric layer and the silicon films.

11. The method of claim 10, wherein the insulating layer is formed by stacking one or more of oxide layers and one or more of nitride layers.

12. The method of claim 10, wherein the insulating layer contain conductive dots of one or more of Ru, Si, Ti and Pt.

13. The method of claim 10, wherein forming the silicon films comprises:
forming a silicon layer over the semiconductor substrate including the top portions of the first isolation layers; and
performing a blanket etch-back process such that the silicon layer remains at both protruding upper sidewalls of each of the first isolation layers.

14. The method of claim 10, wherein each of the silicon films comprises a polysilicon film containing carbon impurities.

15. The method of claim 10, further comprising performing an annealing process to form the silicon layer by converting polysilicon into amorphous silicon.

16. The method of claim 10, further comprising etching the top portions of the first isolation layers and top portions of the second isolation layers to expose upper sidewalls of the silicon films after the second isolation layers are formed.

17. A method of manufacturing a semiconductor device, the method comprising:
forming first isolation layers in a semiconductor substrate, wherein the first isolation layers have protrusions formed at higher positions than the semiconductor substrate;
forming hard mask spacers on both sidewalls of each of the protrusions of the first isolation layers;
forming second isolation layers in the semiconductor substrate between the hard mask spacers, wherein the second isolation layers have protrusions extending higher than the semiconductor substrate;
removing the hard mask spacers;
forming an insulating layer and a silicon layer over the semiconductor substrate between the protrusions of the first and second isolation layers;
forming control gates over the first and second isolation layers and the silicon layer in a direction crossing the first and second isolation layers; and
forming floating gates by removing the silicon layer exposed between the control gates and using the silicon layer remaining under the control gates.

18. The method of claim 17, further comprising etching top portions of the first and second isolation layers before the hard mask spacers are removed.

19. The method of claim 17, further comprising etching top portions of the first and second isolation layers before the control gates are formed.

20. The method of claim 17, wherein forming the control gates comprises:
forming a dielectric layer and a conductive layer over an entire structure including the silicon layer; and
patterning the conductive layer and the dielectric layer in the direction crossing the first and second isolation layers.
